(19) United States
(12) Patent Application Publication
(10) Pub. No.: US 2026/0173976 A1
(43) Pub. Date: Jun. 18, 2026

(54) SEMICONDUCTOR PACKAGE AND METHOD FOR FABRICATING THE SAME

(71) Applicant: SAMSUNG ELECTRONICS CO., LTD., Suwon-si (KR)

(72) Inventors: Hyunsoo CHUNG, Suwon-si (KR); Kwang-Soo KIM, Suwon-si (KR)

(73) Assignee: SAMSUNG ELECTRONICS CO., LTD., Suwon-si (KR)

(21) Appl. No.: 19/239,213

(22) Filed: Jun. 16, 2025

(30) Foreign Application Priority Data
Dec. 17, 2024 (KR) 10-2024-0189079

(51) Int. Cl. H01L 23/498; H01L 23/00; H01L 23/31; H01L 23/52; H01L 25/04

(52) U.S. Cl. CPC H10W 90/701; H10W 70/685; H10W 74/121; H10W 90/00; H10W 72/00; H10W 90/24; H10W 90/754

(57) ABSTRACT

A semiconductor package includes: a redistribution structure; a base die on the redistribution structure; a plurality of conductive posts on the redistribution structure and beside the base die; a first molding material covering the base die and the plurality of conductive posts, on the redistribution structure; a semiconductor stack on the first molding material, wherein the semiconductor stack includes a plurality of core dies, and the plurality of core dies are sequentially stacked with an offset between adjacent two of the plurality of core dies in a stacking direction of the plurality of core dies; a plurality of vertical wires, wherein each of the plurality of vertical wires connects a corresponding core die among the plurality of core dies to a corresponding conductive post among the plurality of conductive posts; and a second molding material covering the semiconductor stack and the plurality of vertical wires, on the first molding material.

### CROSS-REFERENCE TO RELATED APPLICATION

This application claims priority to and the benefit of Korean Patent Application No. 10-2024-0189079 filed with the Korean Intellectual Property Office on Dec. 17, 2024, the entire contents of which are incorporated herein by reference.

### BACKGROUND OF THE INVENTION

### (a) Field of the Invention

The present disclosure relates to a semiconductor package and a method for manufacturing the same.

### (b) Description of the Related Art

A fan-out wafer level package (FOWLP) is a packaging technology that mounts a semiconductor die on a wafer and extends the input/output terminal region under the wafer to the fan out region of the semiconductor die. According to the fan-out wafer level package (FOWLP), the number of input/output terminals disposed under the wafer can be increased, which enables all connections to the input/output terminals of the semiconductor die with fine pitch due to miniaturization and higher integration of the semiconductor die, enables refining the wiring pattern by applying redistribution layer (RDL) technology. Also, since the printed circuit board (PCB) is not used, the thickness of the package can be reduced and the heat dissipation function can be improved.

The function and performance of these fan-out wafer level packages (FOWLPs) are improved as more semiconductor dies are mounted on the wafer. However, if many semiconductor dies are mounted on the wafer, it is difficult to efficiently connect the input/output terminals of each semiconductor die to the wafer due to problems such as difficulty in designing the connection between the wafer and the semiconductor dies according to the stacking structure of the semiconductor dies.

To solve such problems and implement a fan-out wafer level package (FOWLP) with many semiconductor dies mounted on the wafer, vertical wire technology is being researched. A vertical wire is a wiring routing signals or electric power implemented as a straight line. If manufacturing a fan-out wafer level package (FOWLP) using vertical wires, the signal integrity (SI) and electric power integrity (PI) of the semiconductor package can be improved and the size of the semiconductor package can be minimized.

On the other hand, when using vertical wires, the vertical wires may bend depending on their length to cause a defects contacting other adjacent vertical wires, and the vertical wires may be swept by the flow of molding materials during a molding process. Also, as the number of stacked semiconductor dies increases, a large number of vertical wires must be disposed, which may result in the vertical wires being disposed with alignment errors and interference between the vertical wires.

### SUMMARY OF THE INVENTION

A semiconductor package in which each of a plurality of semiconductor dies stacked with an offset is connected to a base die by a two-stage structure of vertical wires and conductive posts may be provided.

A semiconductor package, in which a first spacer structure is disposed on a semiconductor stack, a second spacer structure is placed on a base die, and vertical wires extended without bending are formed using the first spacer structure and the second spacer structure, and a method for manufacturing the semiconductor package may be provided.

A semiconductor package, in which heat generated in a base die and heat generated in a plurality of semiconductor dies are dissipated through spacer structures, may be provided.

A semiconductor package according to an embodiment may include: a redistribution structure; a base die on the redistribution structure; a plurality of conductive posts on the redistribution structure and beside the base die; a first molding material covering the base die and the plurality of conductive posts, on the redistribution structure; a semiconductor stack on the first molding material, wherein the semiconductor stack comprises a plurality of core dies, and the plurality of core dies are sequentially stacked with an offset between adjacent two of the plurality of core dies in a stacking direction of the plurality of core dies; a plurality of vertical wires, wherein each of the plurality of vertical wires connects a corresponding core die among the plurality of core dies to a corresponding conductive post among the plurality of conductive posts; and a second molding material covering the semiconductor stack and the plurality of vertical wires, on the first molding material.

A semiconductor package according to an embodiment may include: a redistribution structure; a buffer die on the redistribution structure; a first conductive post array to an Nth conductive post array on the redistribution structure and beside a side surface of the buffer die, wherein N is a natural number greater than or equal to 2 and each of the first conductive post array to the Nth conductive post array is arranged in a row along the side surface of the buffer die; a first molding material covering the buffer die and the first conductive post array to the N conductive post array, on the redistribution structure; a spacer structure on the first molding material; a memory stack on the spacer structure, wherein the memory stack comprises a first memory die to an Nth memory die, and the first memory die to the Nth memory die are sequentially stacked with an offset between adjacent two memory dies in a stacking direction of the first memory die to the Nth memory die; a first vertical wire array to an Nth vertical wire array, wherein each of the first vertical wire array to the Nth vertical wire array is disposed between a corresponding conductive post array among the first conductive post array to the Nth conductive post array and a corresponding memory die among the first memory die to the Nth memory die, wherein each of the first vertical wire array to the Nth vertical wire array is arranged in a row, on a corresponding conductive post array among the first conductive post array to the Nth conductive post array; and a second molding material covering the spacer structure, the memory stack, and the first vertical wire array to the Nth vertical wire array, on the first molding material.

A semiconductor package according to an embodiment may include: a redistribution structure; a base die on the redistribution structure; a plurality of conductive posts on the redistribution structure and beside a side surface of the base die; a first molding material covering the base die and the plurality of conductive posts, on the redistribution structure; a first dummy structure on the first molding material; a second dummy structure on the base die; a memory stack on the first dummy structure, wherein the memory stack comprises a plurality of core dies, wherein the plurality of core dies are sequentially stacked from a bottom with an offset so as to become closer to the side surface of the base die; a plurality of vertical wires, wherein each of the plurality of vertical wires connects a corresponding core die among the plurality of core dies to a corresponding conductive post among the plurality of conductive posts; and a second molding material covering the first dummy structure, a side surface of the second dummy structure, the memory stack, and the plurality of vertical wires, on the first molding material.

A method for manufacturing a semiconductor package according to an embodiment may include: forming a memory stack by sequentially stacking a plurality of memory dies on a carrier from a bottom with an offset, wherein an active surface of each of the plurality of memory dies faces a direction opposite to the carrier and a portion of the active surface is exposed by the offset; disposing a first dummy structure on the memory stack and disposing a second dummy structure beside the memory stack; forming a plurality of bonding wires such that an exposed active surface of a corresponding memory die among the plurality of memory dies is connected to at least one of the first dummy structure or the second dummy structure, wherein each of the plurality of bonding wires includes a vertical extension portion and a curved extension portion; molding the memory stack, the first dummy structure, the second dummy structure, and the vertical extension portions of the plurality of bonding wires with a first molding material on the carrier; performing a planarization process such that the curved extension portions of the plurality of bonding wires are removed; forming a plurality of conductive posts on the plurality of bonding wires; attaching a base die on the second dummy structure; molding the plurality of conductive posts and the base die with a second molding material on the first molding material; and forming a redistribution structure on the second molding material.

By connecting each of a plurality of semiconductor dies stacked with an offset to a base die with a two-stage structure of vertical wires and conductive posts, the alignment margin between the vertical wires can be improved, and the vertical wires can be aligned uniformly. In addition, short circuits between vertical wires can be prevented and bending stress occurring in the vertical wires can be reduced, which can prevent the vertical wires from being swept.

By forming vertical wires, which extend without bending using the first spacer structure and the second spacer structure, interference between vertical wires can be eliminated, and the input/output terminals of the semiconductor die connected to the vertical wires can be increased, thereby improving the bandwidth of the semiconductor package.

Since heat generated in the base die and heat generated in a plurality of semiconductor dies can be dissipated through the spacer structures, the heat dissipation characteristics of the semiconductor package can be improved.

### BRIEF DESCRIPTION OF THE DRAWINGS

FIG. 1 is a cross-sectional view illustrating a semiconductor package of an embodiment.

FIG. 2 is an enlarged cross-sectional view of the region E of the semiconductor package of FIG. 1.

FIG. 3 is a perspective view illustrating a memory stack of a semiconductor package of an embodiment.

FIG. 4 is a perspective view showing the lower structure of a semiconductor package of an embodiment.

FIG. 5A to FIG. 5D are top plan views illustrating the upper surface of a semiconductor package of an embodiment.

FIG. 6 is a cross-sectional view illustrating the semiconductor package of an embodiment.

FIG. 7 to FIG. 19 are cross-sectional views illustrating a method of manufacturing the semiconductor package of FIG. 1.

### DETAILED DESCRIPTION OF THE EMBODIMENTS

Hereinafter, with reference to accompanying drawings, various embodiments of the present disclosure will be described in detail so that a person of an ordinary skill can easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown.

Throughout the specification, when a part is said to be “connected” to another part, this includes not only “directly connected” but also “indirectly connected” through another member. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

In addition, throughout the specification, when referring to “a plane view”, it means that the target portion is viewed from above, and when referring to “a cross-section view”, it means that a cross section of the target portion cut vertically is viewed from a side.

Hereinafter, an embodiment of a semiconductor package 100, 100A and 100B and a manufacturing method of the semiconductor package 100A will be described with reference to the drawings.

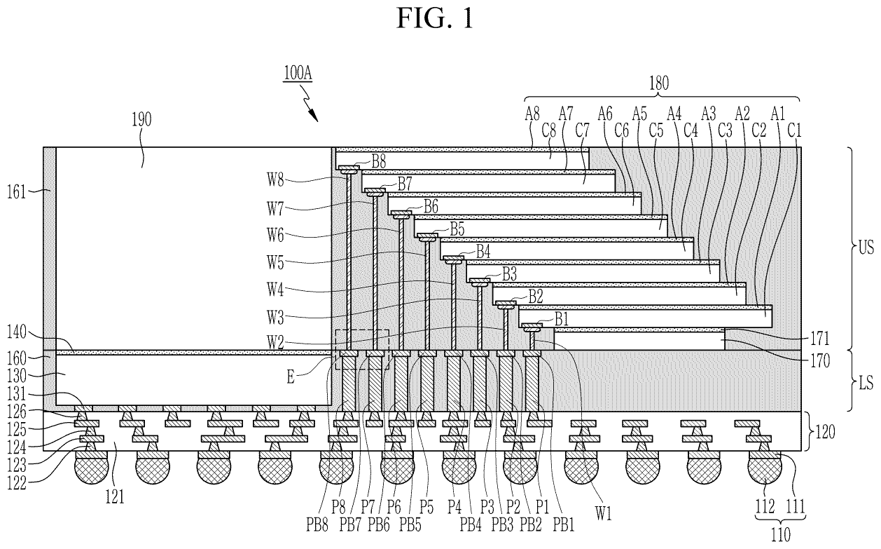

FIG. 1 is a cross-sectional view illustrating a semiconductor package 100A of an embodiment.

Referring to FIG. 1, the semiconductor package 100A may include an external connection structure 110, a redistribution structure 120, a lower structure LS, and an upper structure US. In an embodiment, the semiconductor package 100A may include a System In Package (SIP). The semiconductor package 100A, which implements two or more semiconductor dies into a single semiconductor package, may be operated as a single chip. In an embodiment, the semiconductor package 100A may be a semiconductor package manufactured based on a fan-out wafer level package (FOWLP) or a fan-out panel level package (FOPLP) technology.

The external connection structure 110 may be disposed on a lower surface of the redistribution structure 120. The external connection structure 110 may include conductive pads 111 and external connection members 112. Each of the conductive pads 111 may electrically connect a corresponding first redistribution via 122 of the first redistribution vias 122 of the redistribution structure 120 to a corresponding external connection member 112 of the external connection members 112. The external connection members 112 may electrically connect the semiconductor package 100A to an external device (not shown).

The redistribution structure 120 may be disposed on the external connection structure 110. The redistribution structure 120 may include a dielectric 121, first redistribution vias 122, first redistribution lines 123, second redistribution vias 124, second redistribution lines 125, and third redistribution vias 126, which are disposed in the dielectric 121. In another embodiment, a redistribution structure 120 including a smaller or larger number of redistribution lines and redistribution vias may be included in the scope of the present disclosure.

The dielectric 121 may protect and insulate the first redistribution vias 122, first redistribution lines 123, second redistribution vias 124, second redistribution lines 125, and third redistribution vias 126. On an upper surface of the dielectric 121, connection terminals 131, conductive posts P, and first molding material 160 may be disposed. The conductive pads 111 may be disposed on the lower surface of the dielectric 121.

The first redistribution vias 122, first redistribution lines 123, second redistribution vias 124, second redistribution lines 125, and third redistribution vias 126 are disposed sequentially from a bottom, and may form signal, ground, and electric power routing paths. The first redistribution lines 123 and the second redistribution lines 125 may extend in a horizontal direction within the dielectric 121. The first redistribution vias 122, the second redistribution vias 124, and the third redistribution vias 126 may extend in a vertical direction within the dielectric 121. The first redistribution vias 122, the second redistribution vias 124, and the third redistribution vias 126 may each have a shape of which width in the horizontal direction decreases from the bottom to the top.

The lower structure LS may be disposed on the redistribution structure 120. The lower structure LS may include a base die 130, an adhesive member 140, conductive posts P, bonding pads PB, and a first molding material 160.

The base die 130 may be connected to the redistribution structure 120 by the connection terminals 131. Each of the connection terminals 131 may electrically connect a corresponding wiring of the wirings of the base die 130 to a corresponding third redistribution via 126 of the third redistribution vias 126 of the redistribution structure 120. The base die 130 may include a die base and a front side structure. The base die 130 may include an active surface and a back side, which is the opposite side of the active surface. The base die 130 may be disposed so that the active surface faces the redistribution structure 120. The base die 130 may include a device layer and a wiring layer on the active surface. The device layer may include an integrated circuit structure (IC structure) having integrated circuit regions (IC regions). In an embodiment, the IC structure may include at least one of an active device and a passive device. In an embodiment, the IC structure may include a gate structure, a source region, and a drain region. In an embodiment, the IC structure may include at least one of a transistor, a diode, a capacitor, an inductor, and a resistor. The wiring layer may be disposed on the device layer. The wiring layer may include wiring lines for signals, wiring lines for electric power, contact plugs, and inter-metal dielectric (IMD).

The base die 130 may be a buffer die. The base die 130 can control the memory dies. When data is exchanged between devices with different data processing speeds, processing units, and usage times, data loss may occur due to differences in data processing speeds, processing units, and usage times between devices. To prevent such loss, by disposing the base die 130 between the memory dies C and the external device, information when data is exchanged between the memory dies C and the external device can be temporarily stored in the base die 130. When transmitting data to or receiving data from the memory dies C, the base die 130 may sequentially pass the data after arranging the order of the data.

The adhesive member 140 may be disposed on the back side of the base die 130. The adhesive member 140 may attach the base die 130 to the second spacer structure 190.

The conductive posts P may be disposed on the redistribution structure 120. The conductive posts P may be disposed beside the base die 130. A first conductive post P1 among the conductive posts P may be connected to the first memory die C1. An Nth conductive post PN among the conductive posts P may be connected to the Nth memory die CN. Here, N may be a natural number greater than or equal to 2. In FIG. 1, eight conductive posts P (a first conductive post P1 to an eighth conductive post P8) are illustrated, but, not limited thereto, the conductive posts P more or less than eight (a first conductive post P1 to a Nth conductive post PN, N is more or less than eight) may be included in the scope of the present disclosure. Each of the conductive posts P may be disposed between a corresponding third redistribution via 126 of the third redistribution vias 126 of the redistribution structure 120 and a corresponding bonding pad PB of the bonding pads PB. Each of the conductive posts P may electrically connect a corresponding bonding pad PB of the bonding pads PB to a corresponding third redistribution via 126 of the third redistribution vias 126 of the redistribution structure 120. The conductive posts P may be disposed penetrating the first molding material 160. The side surfaces of the conductive posts P may be surrounded by the first molding material 160.

The bonding pads PB may be disposed on the conductive posts P. A first bonding pad PB1 among the bonding pads PB may be connected to the first memory die C1. An Nth bonding pad PBN among the bonding pads PB may be connected to the Nth memory die CN. Here, N may be a natural number greater than or equal to 2. In FIG. 1, eight bonding pads PB (a first bonding pad PB1 to an eighth bonding pad PB8) are illustrated. However, not limited thereto, the bonding pads PB more or less than eight (a first bonding pad PB1 to an Nth bonding pad PBN, N is more or less than eight) may be included in the scope of the present disclosure. Each of the bonding pads PB may be disposed between a corresponding conductive post P of the conductive posts P and a corresponding vertical wire W of the vertical wires W. Each of the bonding pads PB may electrically connect the corresponding vertical wire W of the vertical wires W to the corresponding conductive post P of the conductive posts P.

The first molding material 160 may cover the base die 130, the connection terminals 131, the adhesive member 140, the conductive posts P, and the bonding pads PB, on the redistribution structure 120. The first molding material 160 may protect the base die 130, the connection terminals 131, the adhesive member 140, the conductive posts P, and the bonding pads PB from the external environment, and thereby the electrical or mechanical stability of the semiconductor package 100A can be ensured.

The upper structure US may be disposed on the lower structure LS. The upper structure US may include a first spacer structure 170, an adhesive member 171, a memory stack 180, a second spacer structure 190, and a second molding material 161.

The first spacer structure (first dummy structure; 170) may be disposed on the first molding material 160. The first spacer structure 170 may support the memory stack 180. A footprint of the first spacer structure 170 may be included within a footprint of the first memory die C1 of the memory stack 180. The first spacer structure 170 may be electrically isolated from the memory dies C and other components. In an embodiment, the first spacer structure 170 may include a conductive material having high thermal conductivity, such as copper or aluminum, or a silicon material.

The adhesive member 171 may be disposed between the first spacer structure 170 and the memory stack 180. The adhesive member 171 may attach the first spacer structure 170 to the memory stack 180.

The memory stack (semiconductor stack; 180) may be disposed on the first spacer structure 170. The memory stack 180 may include memory dies C and adhesive members A. In the memory stack 180, the memory dies C and the adhesive members A may be stacked alternately.

The memory dies (semiconductor die; core die; C) may include a first memory die C1 to an Nth memory die CN. Here, N may be a natural number greater than or equal to 2. The more memory dies C the memory stack(S) includes in the semiconductor package 100A, the more improved the function and performance of the semiconductor package 100A are. However, if forming a memory stack(S) with too many memory dies C, it causes problems such as difficulty in designing connections between the conductive posts P and the memory dies C according to the stacking structure of the memory stack (S), due to variables such as the aspect ratio of the vertical wire W that affects the sweep of the vertical wire W, the junction strength of the material used for the vertical wire W, and the alignment error of the vertical wire W. Therefore, N may be determined considering the function and performance of the semiconductor package 100A, and the connection between the conductive posts P and the memory dies C. Although the drawing according to the present disclosure illustrates a memory stack(S) with N of 8, not limited thereto, a memory stack(S) including a smaller or larger number of memory dies C may be included in the present disclosure.

The first memory die C1 to the Nth memory die CN may be stacked sequentially with an offset from the bottom. The first memory die C1 to the Nth memory die CN may be disposed so as to become closer to the base die 130 in order from the first memory die C1 to the Nth memory die CN (in a direction to a side surface of the base die 130). The first memory die C1 to the Nth memory die CN may be disposed such that each footprint of the first memory die C1 to the Nth memory die CN becomes closer to the footprint of the base die 130 in order from the first memory die C1 to the Nth memory die CN. The Nth memory die CN may be exposed to the outside from the second molding material 161.

The memory die C may include an active surface and a back side, which is the opposite side of the active surface. The memory die C may be disposed so that the active surface faces the redistribution structure 120. The memory die C may include a device layer and a wiring layer on the active surface. The device layer may include an integrated circuit structure (IC structure) having integrated circuit regions (IC regions). In an embodiment, the IC structure may include at least one of an active device and a passive device. In an embodiment, the IC structure may include a memory cell array, a transistor, a capacitor, an inductor, or a resistor. The wiring layer may be disposed on the device layer. The wiring layer may include wiring lines for signals, wiring lines for electric power, contact plugs, and inter-metal dielectric (IMD). In an embodiment, the first memory die C1 to the Nth memory die CN may include a volatility or a non-volatile memory die.

Each of the first memory die C1 to the Nth memory die CN may include a corresponding connection pad B among the first connection pads B1 to the Nth connection pads (BN) arranged on the active surface. A portion of the active surface of the first memory die C1 is covered by the first spacer structure 170, and the remaining portion of the active surface of the first memory die C1 may not be covered by the first spacer structure 170 and exposed. The first connection pads B1 may be disposed on the exposed portion of the active surface of the first memory die C1. A portion of the active surface of the Nth memory die CN is covered by the neighboring N-1th memory die CN-1, and the remaining portion of the active surface of the Nth memory die CN may not be covered by the N-1th memory die CN-1 and exposed. The Nth connection pads BN may be disposed on the exposed portion of the active surface of the Nth memory die CN. Each of the connection pads B may electrically connect a corresponding vertical wire W among the vertical wires W to a semiconductor device of a corresponding memory die C among the memory dies C. In an embodiment, the connection pads B may comprise at least one of copper, nickel, zinc, gold, silver, platinum, palladium, chromium, titanium, and alloys thereof.

The adhesive members A may be disposed alternately with memory dies C. The first adhesive member A1 among the adhesive members A may be attached to the first memory die C1. The Nth adhesive member AN among the adhesive members A may be attached to the Nth memory die CN. Here, N may be a natural number greater than or equal to 2. The first adhesive member A1 may attach the first memory die C1 and the second memory die C2. The N-1th adhesive member AN-1 may attach the N-1th memory die CN-1 and the Nth memory die CN.

The vertical wires W may connect the memory stack 180 to the conductive posts P. The first vertical wires W1 among the vertical wires W may be connected to the first memory die C1. The Nth vertical wire WN among the vertical wires W may be connected to the Nth memory die CN. Here, N may be a natural number greater than or equal to 2. In FIG. 1, eight vertical wires W (a first vertical wire W1 to an eighth vertical wire W8) are illustrated. However, not limited thereto, the vertical wires W more or less than eight (a first vertical wire W1 to an Nth vertical wire WN, N is more or less than eight) may be included in the scope of the present disclosure.

A vertical wire is a wiring routing signals or electric power implemented in a vertical form. Each of the vertical wires W may be disposed between a corresponding memory die C among the memory dies C and a corresponding conductive post P among the conductive posts P. Each of the vertical wires W may be electrically connected to a corresponding memory die C among the memory dies C to a corresponding conductive post P among the conductive posts P through a corresponding bonding pad PB among the bonding pads PB. A first end of each of the vertical wires W may be connected to a corresponding conductive post P among the conductive posts P through a corresponding bonding pad PB among the bonding pads PB. A second end, which is opposite to each first end, of each of the vertical wires W may be connected to a corresponding connection pad B among the connection pads B of a corresponding memory die C among the memory dies C. In an embodiment, the vertical wires W may comprise at least one of gold, silver, copper, lead, platinum, and alloys thereof. In an embodiment, each of the vertical wires W may have an aspect ratio of diameter to height of about 1:5 to about 1:15.

The second spacer structure (second dummy structure; 190) may be disposed on the base die 130. The second spacer structure 190 may be attached to the base die 130 by the adhesive member 140. The second spacer structure 190 may be electrically isolated from the base die 130, from the memory dies C, and from other components. The second spacer structure 190 may be a heat dissipation structure. The second spacer structure 190 may be thermally connected to the base die 130. The second spacer structure 190 may be exposed to the outside from the second molding material 161. In an embodiment, the second spacer structure 190 may include a conductive material having high thermal conductivity, such as copper or aluminum, or a silicon material. By disposing the second spacer structure 190 on the base die 130, heat generated at the base die 130 can be dissipated through the second spacer structure 190, and thereby, the heat dissipation characteristics of the semiconductor package 100A can be improved.

The second molding material 161 may cover the first spacer structure 170, the adhesive member 171, the memory stack 180, and the second spacer structure 190, on the lower structure LS. The second molding material 161 may protect the first spacer structure 170, the adhesive member 171, the memory stack 180, and the second spacer structure 190 from the external environment, and thereby, the electrical or mechanical stability of the semiconductor package 100A can be ensured.

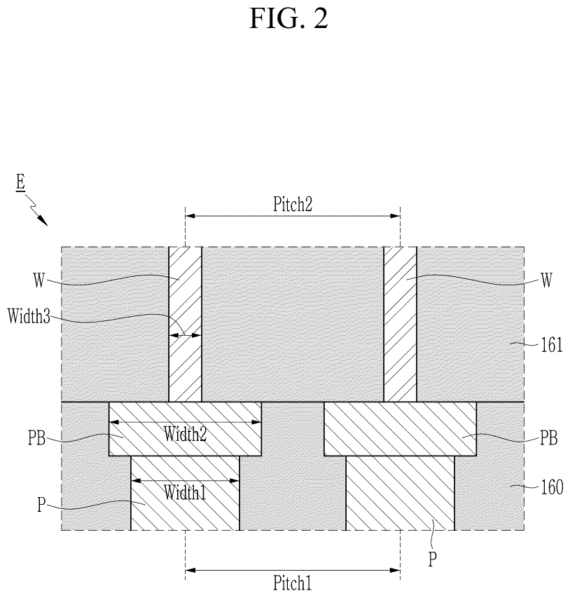

FIG. 2 is an enlarged cross-sectional view of the region E of the semiconductor package 100A of FIG. 1.

Referring to FIG. 2, each of the vertical wires W may be connected to a corresponding conductive post P among the conductive posts P through a corresponding bonding pad PB among the bonding pads PB. Each of the conductive posts P may have a first width (Width1) in the horizontal direction. Each of the bonding pads PB may have a second width (Width2) in the horizontal direction. Each of the vertical wires W may have a third width (Width3) in the horizontal direction. The first width (Width1) may be smaller than the second width (Width2). The third width (Width3) may be smaller than the first width (Width1). The conductive posts P may be arranged with a first pitch (Pitch1) in the horizontal direction. The vertical wires W may be arranged with a second pitch (Pitch2) in the horizontal direction. The first pitch (Pitch1) may be equal to the second pitch (Pitch2).

In this way, the memory dies C and the base die 130 may be connected using a two-stage structure of the vertical wires W and the conductive posts P. Since the vertical wires W may be aligned according to the alignment of the conductive posts P having a first width (Width1) greater than the third width (Width3) of the vertical wires W, the alignment margin between the vertical wires W can be improved, and the vertical wires W can be uniformly arranged according to the arrangement of the conductive posts P.

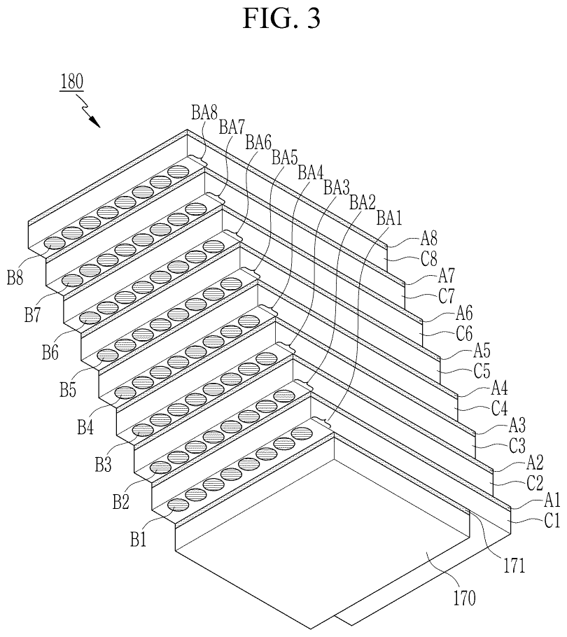

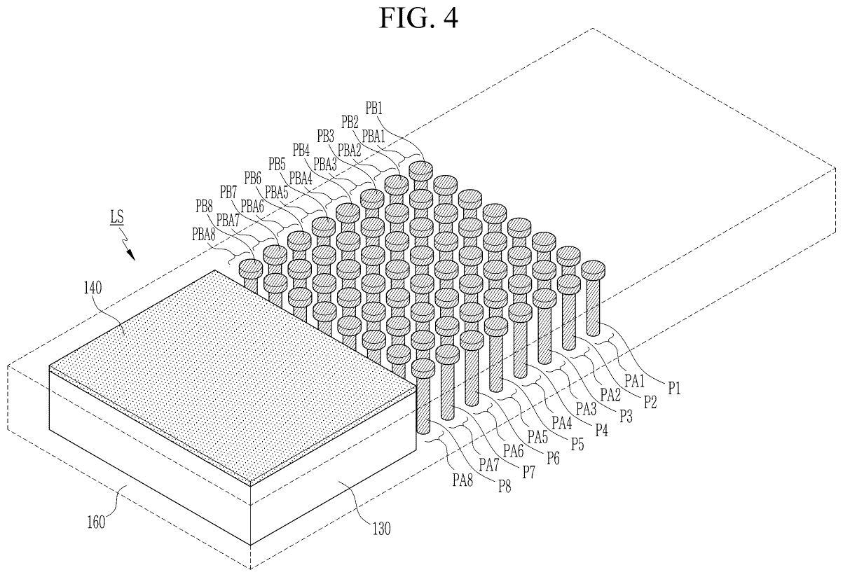

FIG. 3 is a perspective view illustrating a memory stack 108 of a semiconductor package 100A of an embodiment. FIG. 4 is a perspective view showing the lower structure LS of a semiconductor package 100A of an embodiment.

Referring to FIG. 3, a connection pad array BA may be disposed on each active surface of the first memory die C1 to the Nth memory die CN which are sequentially stacked with an offset from the bottom. A first connection pad array BA1 may be disposed on the active surface of the first memory die C1. The first connection pad array BA1 may include a plurality of first connection pads P1 arranged in a row. An Nth connection pad array BAN may be disposed on the active surface of the Nth memory die CN. An Nth connection pad array BAN may include a plurality of Nth connection pad PN arranged in a row. Here, N may be a natural number greater than or equal to 2. In FIG. 3, one connection pad array BA is arranged on an active surface of each of the first memory die C1 to the Nth memory die CN, but not limited thereto, a plurality of connection pad arrays BA may be arranged on the active surface of each of the first memory die C1 to the Nth memory die CN.

Referring to FIG. 4, in the lower structure LS, the conductive post arrays (PA) may be beside a side surface of the base die 130. The conductive post arrays (PA) may be arranged conformally and in a row along a side surface of the base die 130. The first conductive post array PA1 may include a plurality of first conductive posts P1 arranged in a row. An Nth conductive post array PAN may include a plurality of Nth conductive post PN arranged in a row. Here, N may be a natural number greater than or equal to 2. The first conductive post array PA1 to the Nth conductive post array PAN may be disposed so as to become closer to the base die 13 in order from the first conductive post array PA1 to the Nth conductive post array PAN.

In the lower structure LS, the bonding pad arrays PBA may be disposed beside a side surface of the base die 130 and on the conductive post arrays (PA). The bonding pad arrays PBA may be arranged conformally and in a row along a side surface of the base die 130. The first bonding pad array PBA1 may include a plurality of first bonding pads PB1 arranged in a row. The Nth bonding pad array PBAN may include a plurality of bonding pad PBN arranged in a row. Here, N may be a natural number greater than or equal to 2. The first bonding pad array PBA1 to the Nth bonding pad array PBAN may be disposed so as to become closer to the base die 130 in order from the first bonding pad array PBA1 to the Nth bonding pad array PBAN.

Referring to FIG. 1, FIG. 3 and FIG. 4, each of the vertical wire arrays WA may be disposed between a corresponding conductive post array PA among the conductive post arrays (PA) and a corresponding memory die C among the memory dies C. Each of the vertical wire arrays WA may connect a corresponding memory die C among the memory dies C to a corresponding conductive post array PA among the conductive post arrays (PA) through a corresponding bonding pad arrays PBA among the bonding pad arrays PBA. The first vertical wire array WA1 may include a plurality of first vertical wires W1 arranged in a row. The Nth vertical wire array WAN may include a plurality of vertical wires WN arranged in a row. Here, N may be a natural number greater than or equal to 2. The first vertical wire array WA1 to the Nth vertical wire array WAN may be disposed so as to become closer to the second spacer structure 190 or the base die 130 in order from the first vertical wire array WA1 to the Nth vertical wire array WAN. Each of the first vertical wire array WA1 to the Nth vertical wire array WAN may be arranged in a row on a corresponding conductive post array PA among the first conductive post array PA1 to the Nth conductive post array PAN.

In this way, each of the first memory die C1 to the Nth memory die CN may be electrically connected to the base die 130 through a corresponding vertical wire array WA among the first vertical wire array WA1 to the Nth vertical wire array WAN, a corresponding bonding pad arrays PBA among the first bonding pad arrays PBA to the Nth bonding pad array PBAN, a corresponding conductive post array PA among the first conductive post array PA1 to the Nth conductive post array PAN, and the redistribution structure 120.

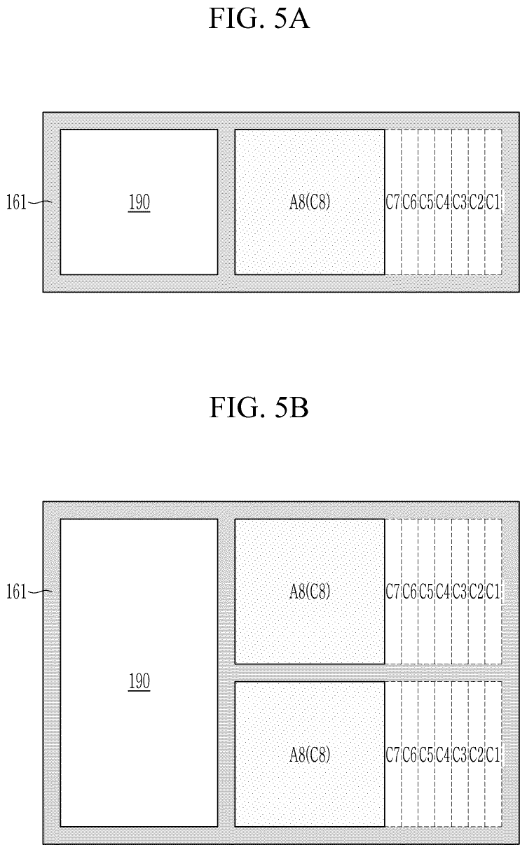

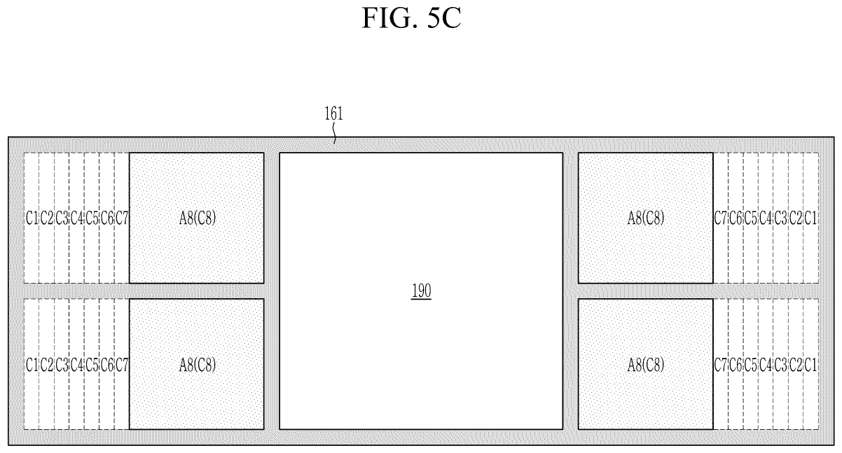

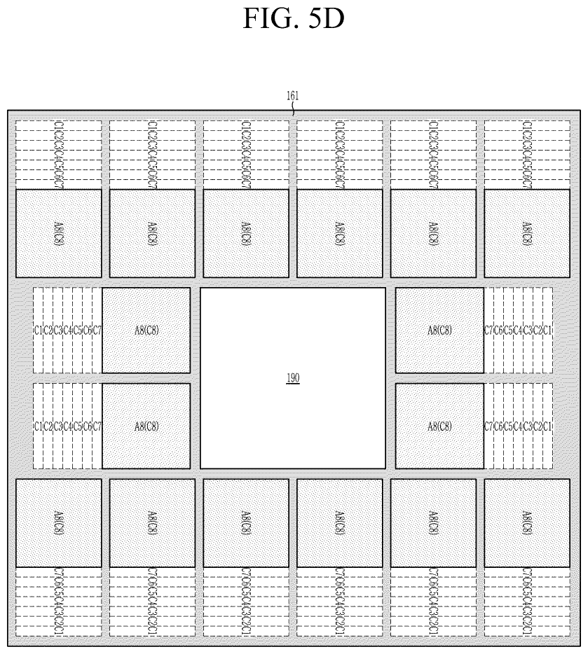

FIG. 5A to FIG. 5D are top plan views illustrating the upper surface of a semiconductor package 100A of an embodiment.

Referring to FIG. 5A to FIG. 5D, various embodiments are shown regarding the number and arrangement of memory stacks 180. In an embodiment, the memory stack 180 including a first memory die C1 to an Nth memory die CN may be disposed beside a side surface of the second spacer structure 190 on the base die 130 (see FIG. 5A). In an embodiment, a plurality of memory stacks 180 including a first memory die C1 to an Nth memory die CN may be disposed beside a side surface of the second spacer structure 190 on the base die 130 (see FIG. 5B). In an embodiment, the memory stack 180 including a first memory die C1 to an Nth memory die CN may be disposed beside a first side of a second spacer structure 190 on a base die 130 and a second side opposite to the first side (see FIG. 5C). In an embodiment, a memory stack 180 including a first memory die C1 to an Nth memory die CN may be disposed beside all side surfaces of a second spacer structure 190 on a base die 130 (see FIG. 5D).

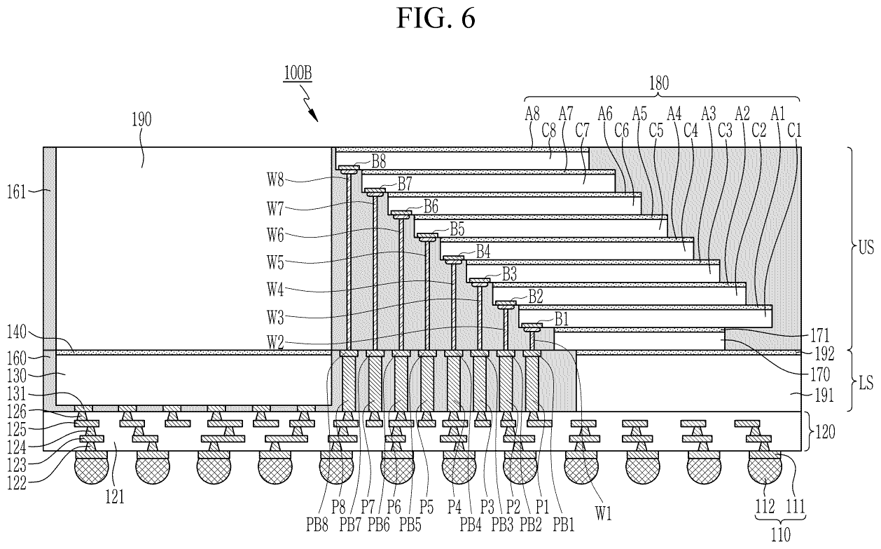

FIG. 6 is a cross-sectional view illustrating a semiconductor package 100B of an embodiment.

Referring to FIG. 6, the semiconductor package 100B may include a third spacer structure (third dummy structure; 191). The third spacer structure 191 may be included within the lower structure LS. The third spacer structure 191 may be disposed between the redistribution structure 120 and the first spacer structure 170. The third spacer structure 191 may be attached to the second molding material 161 by the adhesive member 192. The third spacer structure 191 may be in contact with and thermally connected to the first spacer structure 170. The third spacer structure 191 may be covered by the first molding material 160. The third spacer structure 191 may be exposed to the outside from the first molding material 160 through the side surface of the semiconductor package 100B. The third spacer structure 191 may be electrically isolated from the base die 130, from the memory dies C, and from other components.

The first spacer structure 170 and the third spacer structure 191 may be heat dissipation structures. The first spacer structure 170 and the third spacer structure 191 may be thermally connected to the memory dies C. In an embodiment, the first spacer structure 170 and the third spacer structure 191 may comprise a conductive material having high thermal conductivity, such as copper or aluminum, or a silicon material. By disposing the third spacer structure 191 so as to contact the first spacer structure 170, heat generated in the memory dies C can be dissipated outside through the first spacer structure 170 and the third spacer structure 191, and thereby the heat dissipation characteristics of the semiconductor package 100B can be improved.

The adhesive member 192 may be disposed between the second molding material 161 and the third spacer structure 191, and between the first spacer structure 170 and the third spacer structure 191. The adhesive member 192 may attach the third spacer structure 191 to the second molding material 161, and the third spacer structure 191 to the first spacer structure 170.

As for contents other than those described for semiconductor package 100B of an embodiment in FIG. 6, the contents described for semiconductor package 100A in FIG. 1 to FIG. 5D may be applied.

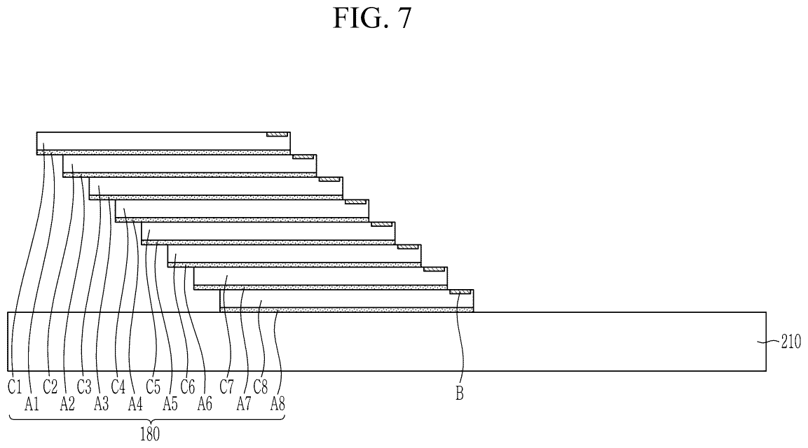

FIG. 7 to FIG. 19 are cross-sectional views illustrating a method of manufacturing the semiconductor package of FIG. 1. The method of FIG. 7 to FIG. 19 for manufacturing the semiconductor package 100A of an embodiment of FIG. 1 may be applied to a method for manufacturing the semiconductor package 100B of FIG. 6.

FIG. 7 is a cross-sectional view illustrating a step of forming a semiconductor stack 180 on a carrier 210.

Referring to FIG. 7, a carrier 210 may be provided. The carrier 210 may comprise a silicon-based material such as glass or silicon oxide, another material such as organic material or aluminum oxide, or any combination of these materials. And, using adhesive members A, the first memory die C1 to the Nth semiconductor die CN may be sequentially stacked on the carrier 210. The first memory die C1 to the Nth memory die CN may be stacked such that an active surface of each of the first memory die C1 to the Nth memory die CN faces the opposite direction of the carrier 210. The first memory die C1 to the Nth memory die CN may be stacked with an offset in the horizontal direction such that a portion of an active surface of each of the first memory die C1 to the Nth memory die CN is exposed, and the first connection pads B1 to the Nth connection pads (BN) are exposed. In an embodiment, the adhesive members A may include a die attach film (DAF). In an embodiment, the adhesive members A may include a thermal interface material (TIM). The thermal interface material (TIM) may be inserted between the memory dies C to improve thermal coupling between the memory dies C. The thermal interface material (TIM) may fill the air layer of the contact surface between memory dies C to reduce thermal contact resistance. In an embodiment, the thermal interface material (TIM) may include thermal paste, thermal pad, phase change material (PCM), metal material, or grease.

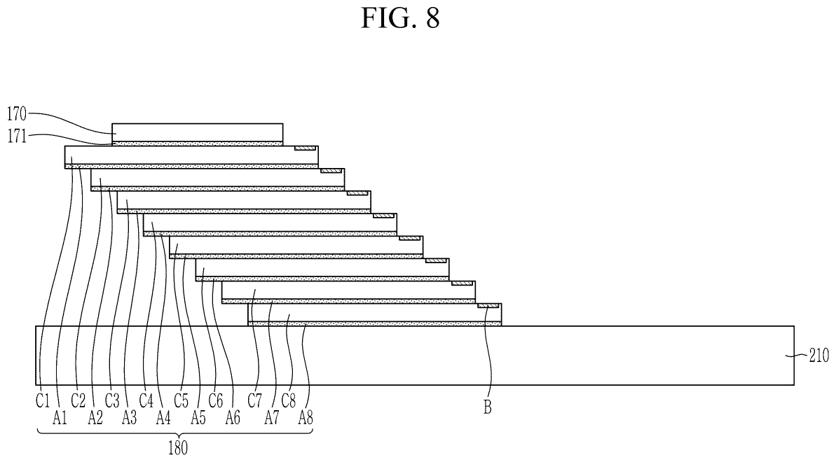

FIG. 8 is a cross-sectional view illustrating a step of attaching the first spacer structure 170 onto the semiconductor stack 180.

Referring to FIG. 8, the first spacer structure 170 may be attached to the semiconductor stack 180 by the adhesive member 171. In an embodiment, the adhesive member 171 may include a die attach film (DAF). In an embodiment, the adhesive members 171 may include a thermal interface material (TIM).

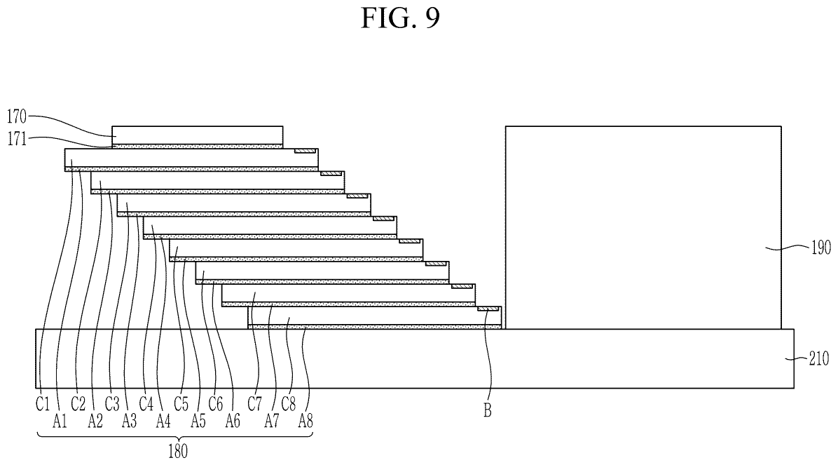

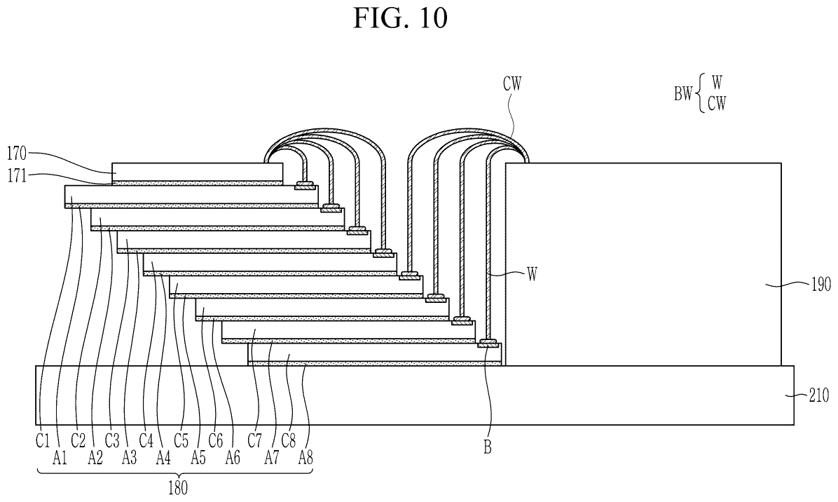

FIG. 9 is a cross-sectional view illustrating a step of attaching the second spacer structure 190 onto the carrier 210.

Referring to FIG. 9, the second spacer structure 190 may be attached to the carrier 210 by an adhesive member (not shown). The second spacer structure 190 may be disposed beside the semiconductor stack 180. In an embodiment, the adhesive member (not shown) may include a die attach film (DAF). In an embodiment, the adhesive member (not shown) may include a thermal interface material (TIM).

FIG. 10 is a cross-sectional view illustrating a step of forming the bonding wires BW.

Referring to FIG. 10, the bonding wires BW may be formed that a corresponding connection pad B of connection pads B on the exposed active surface of the memory die C is connected to at least one of, the first spacer structure 170 and the second spacer structure 190.

First, the capillary is aligned on the connection pad B, and an end of the wire may be shaped into a ball using the capillary. In an embodiment, the ball may be formed by applying heat to the tip of the capillary, or by applying a spark to an end of the wire. Next, the ball may be bonded onto the connection pad B using the capillary. In an embodiment, the ball may be bonded to the connection pad B by applying heat to the capillary, applying pressure to the capillary, or applying ultrasonic vibration to the capillary. And then, the wire pressed to the connection pad B may be stretched to form the vertical wire W, and the capillary may be moved a predetermined distance so that the end of the wire can be bonded to at least one of the first spacer structure 170 and the second spacer structure 190. The end of the wire corresponds to an opposite part of the ball pressed onto the connection pad B. Each of the bonding wires BW may include a vertical wire W extending in the vertical direction and a bent wire CW extending with bend from the vertical wire W toward at least one of the first spacer structure 170 and the second spacer structure 190.

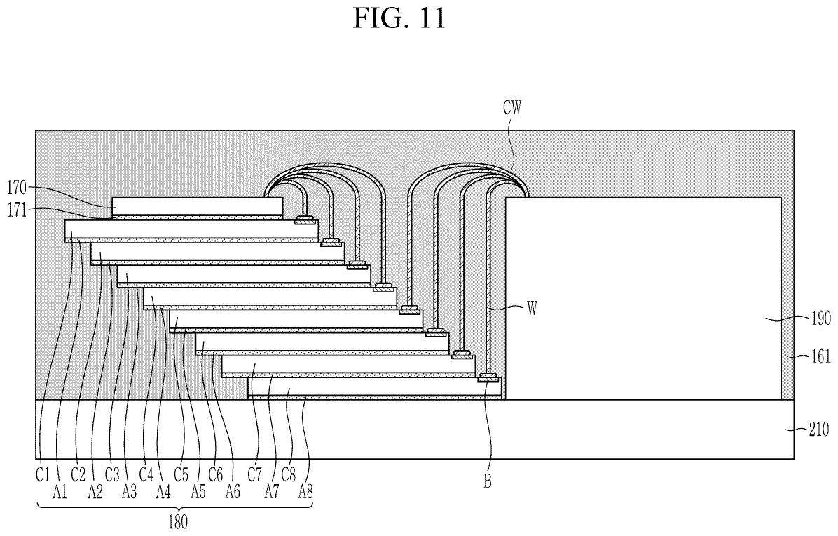

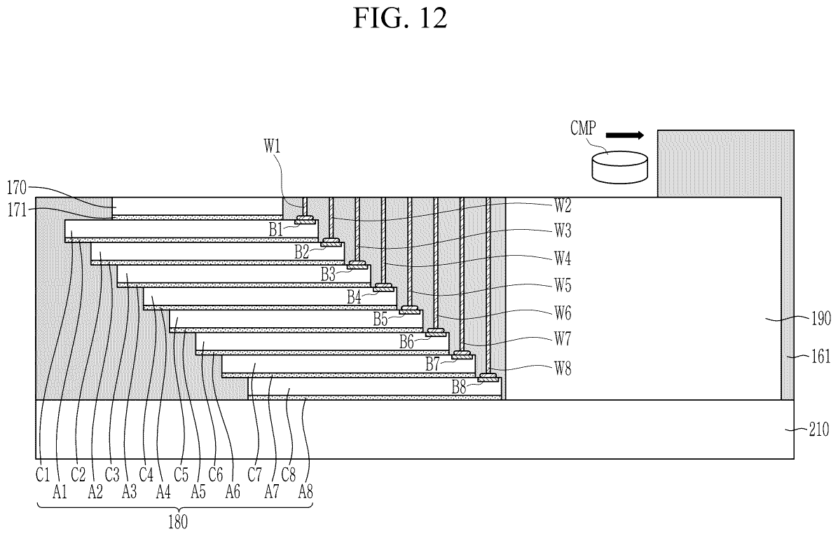

FIG. 11 is a cross-sectional view illustrating a step of molding the first spacer structure 170, the semiconductor stack 180, the second spacer structure 190, and the bonding wires BW, on the carrier 210.

Referring to FIG. 11, on the carrier 210, the first spacer structure 170, the semiconductor stack 180, the second spacer structure 190, and the bonding wires BW may be molded with the second molding material 161. As an embodiment, the process of molding with the second molding material 161 may include a compression molding or transfer molding process. In an embodiment, the second molding material 161 may include an epoxy molding compound (EMC).

FIG. 12 is a cross-sectional view illustrating a step of performing a chemical mechanical polishing (CMP) process on the second molding material 161.

Referring to FIG. 12, a chemical mechanical polishing (CMP) process may be performed to level the upper surface of the second molding material 161 and to remove the bending wires CW of the bonding wires BW. After performing the chemical mechanical polishing (CMP) process, the ends of the first spacer structure 170, the second spacer structure 190, and the vertical wires W may be exposed. In an embodiment, the width of the vertical wires W may be from about 10μm to about 100μm. In an embodiment, the height of the vertical wires W may be from about 40μm to about 800μm.

According to the present disclosure, the vertical wires W may be formed by removing the bent wires CW of the bonding wires BW after eliminating interference between the bonding wires BW by connecting the bonding wires BW to the first spacer structure 170 or the second spacer structure 190. Thereby, the alignment margin between vertical wires W can be improved, and short circuits between vertical wires W by uniformly aligned vertical wires W can be prevented. Also, the vertical wires W can be prevented from being swept during the molding process by reducing the bending stress occurring in the vertical wires W. In addition, the bandwidth of the semiconductor package 100A can be improved by increasing the input/output terminals of the memory die C connected to the vertical wires W based on such arrangement of vertical wires W.

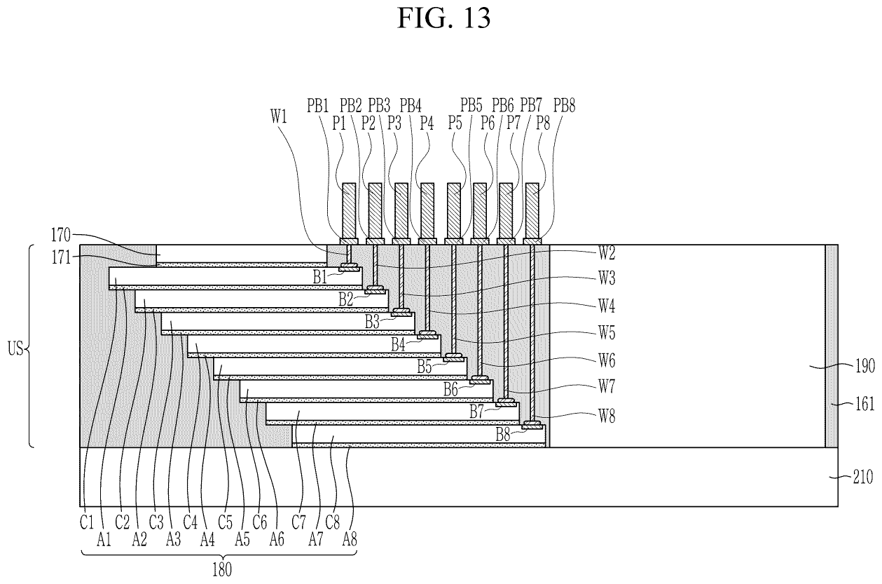

FIG. 13 is a cross-sectional view illustrating a step of forming the bonding pads PB on the vertical wires W and forming conductive posts P on the bonding pads PB.

Referring to FIG. 13, the bonding pads PB may be formed on the vertical wires W, and the conductive posts P may be formed on the bonding pads PB. Each of the bonding pads PB may be formed so as to be disposed on a corresponding vertical wire W among the vertical wires W. Each of the conductive posts P may be formed so as to be disposed on a corresponding bonding pad PB among the bonding pads PB. The bonding pads PB and the conductive posts P may be formed by additionally depositing photoresist on the upper structure US, selectively exposing and developing the photoresist to form a photoresist pattern including openings, and filling the openings with a conductive material. In an embodiment, the bonding pads PB and the conductive posts P may be formed by performing a sputtering process, or by performing an electrolytic plating process after forming a seed metal layer. In an embodiment, the bonding pads PB and the conductive posts P may comprise at least one of copper, aluminum, tungsten, nickel, gold, silver, chromium, antimony, tin, titanium, and alloys thereof.

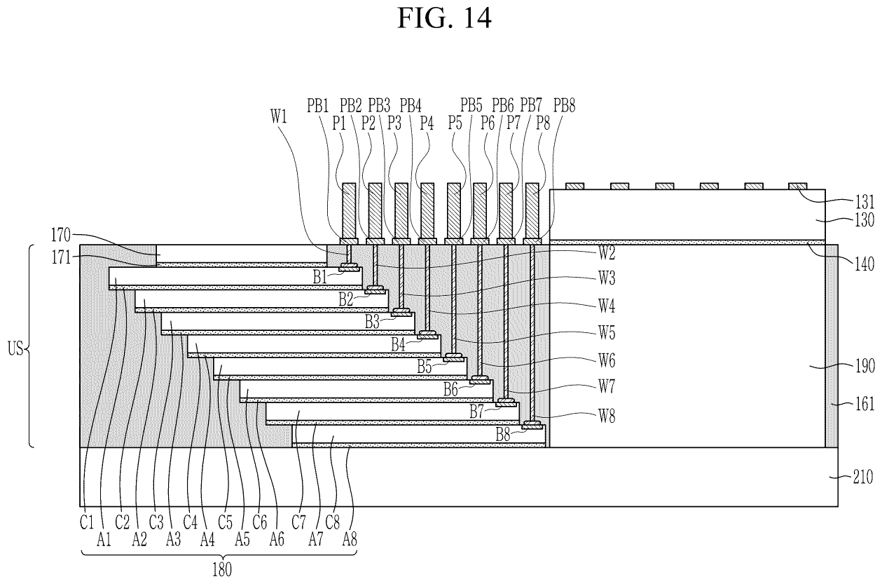

FIG. 14 is a cross-sectional view illustrating a step of attaching the base die 130 onto the second spacer structure 190.

Referring to FIG. 14, the base die 130 may be attached to the second spacer structure 190 by the adhesive member 140. In an embodiment, the adhesive member 140 may include a die attach film (DAF). In an embodiment, the adhesive members 140 may include a thermal interface material (TIM).

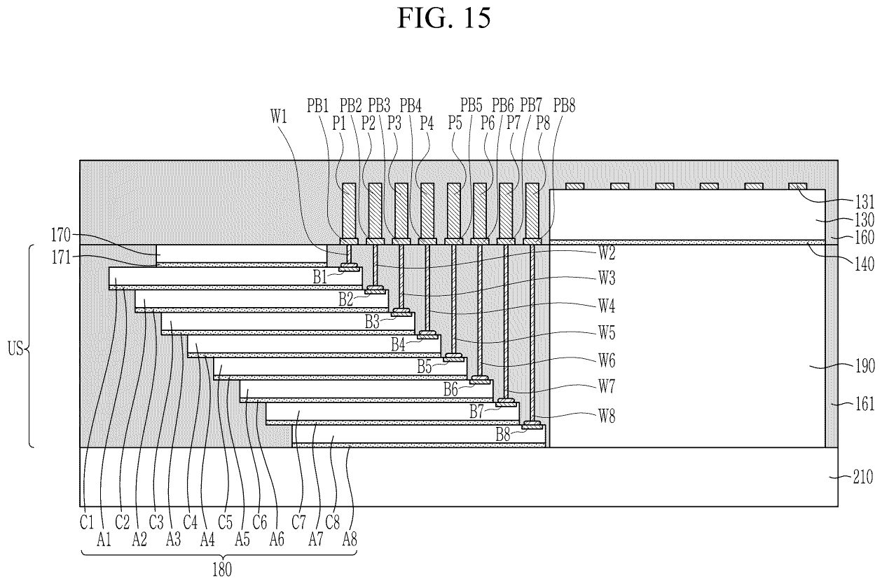

FIG. 15 is a cross-sectional view illustrating a step of molding the bonding pads PB, the conductive posts P, and the base die 130 on the upper structure US.

Referring to FIG. 15, the bonding pads PB, the conductive posts P, and the base die 130 may be molded on the upper structure US using the first molding material 160. As an embodiment, the process of molding with the first molding material 160 may include a compression molding or transfer molding process. In an embodiment, the first molding material 160 may include an epoxy molding compound (EMC).

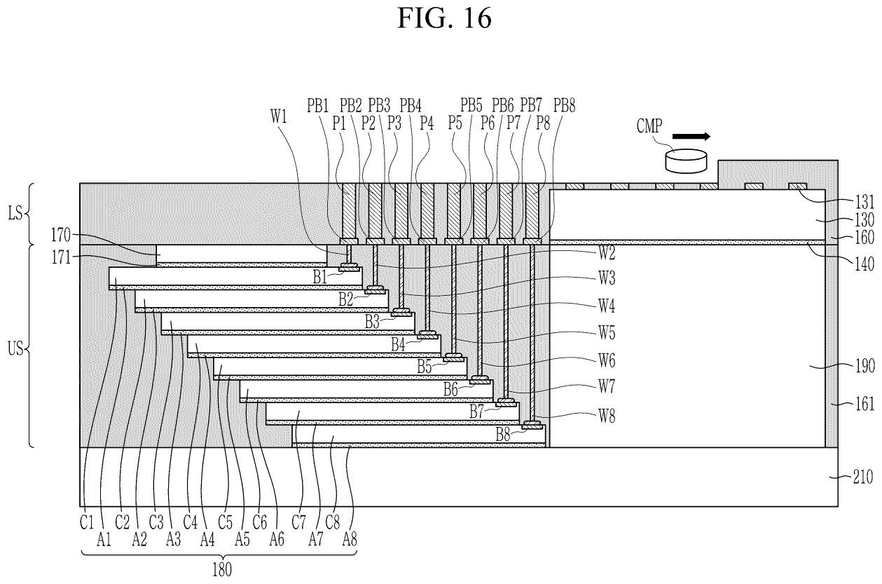

FIG. 16 is a cross-sectional view illustrating a step of performing a chemical mechanical polishing (CMP) process on the first molding material 160.

Referring to FIG. 16, a chemical mechanical polishing (CMP) process may be performed to level the upper surface of the first molding material 160. After performing the chemical mechanical polishing (CMP) process, the upper surfaces of the conductive posts P and the upper surfaces of the connection terminals 131 on the base die 130 may be exposed.

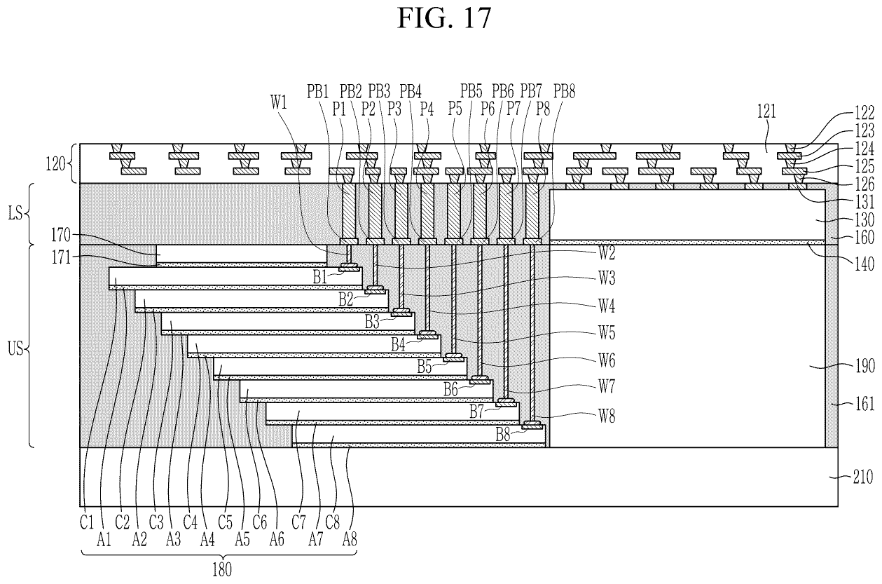

FIG. 17 is a cross-sectional view illustrating a step of forming the redistribution structure 120 on the lower structure LS.

Referring to FIG. 17, the redistribution structure 120 may be formed on the lower structure LS. The third redistribution vias 126, the second redistribution lines 125, the second redistribution vias 124, the first redistribution lines 123, and the first redistribution vias 122 may be formed sequentially from the bottom, in a way of forming a dielectric 121 on the lower structure LS, and then selectively etching the dielectric 121 to form openings and filling the openings with a conductive material.

The dielectric 121 may be deposited by performing a spin coating process. In an embodiment, the dielectric 121 may include a photoimageable dielectric material (PID) used in the redistribution layer process. As an embodiment, the photoimageable dielectric material (PID) may include a polyimide-based photoimageable polymer, a novolak-based photoimageable polymer, a polybenzoxazole, a silicon-based polymer, an acrylate-based polymer, or an epoxy-based polymer. In an embodiment, a photoresist process and an etching process are performed to etch the dielectric 121, and thereby openings in the dielectric 121 may be formed. Since the first redistribution vias 122, the second redistribution vias 124, and the third redistribution vias 126 are formed later by the chip-first process, each of the first redistribution vias 122, the second redistribution vias 124, and the third redistribution vias 126 may have a shape of which the width in the horizontal direction increases from the bottom to the top. In the final product semiconductor package 100A, each of the first redistribution vias 122, the second redistribution vias 124, and the third redistribution vias 126 may have a shape of which the width in the horizontal direction decreases from the bottom to the top. In an embodiment, the first redistribution vias 122, the first redistribution lines 123, the second redistribution vias 124, the second redistribution lines 125, and the third redistribution vias 126 may be formed by performing a sputtering process or by performing an electrolytic plating process after forming a seed metal layer. In an embodiment, each of the first redistribution vias 122, the first redistribution lines 123, the second redistribution vias 124, the second redistribution lines 125, and the third redistribution vias 126 may comprise at least one of copper, aluminum, tungsten, nickel, gold, tin, titanium, and alloys thereof.

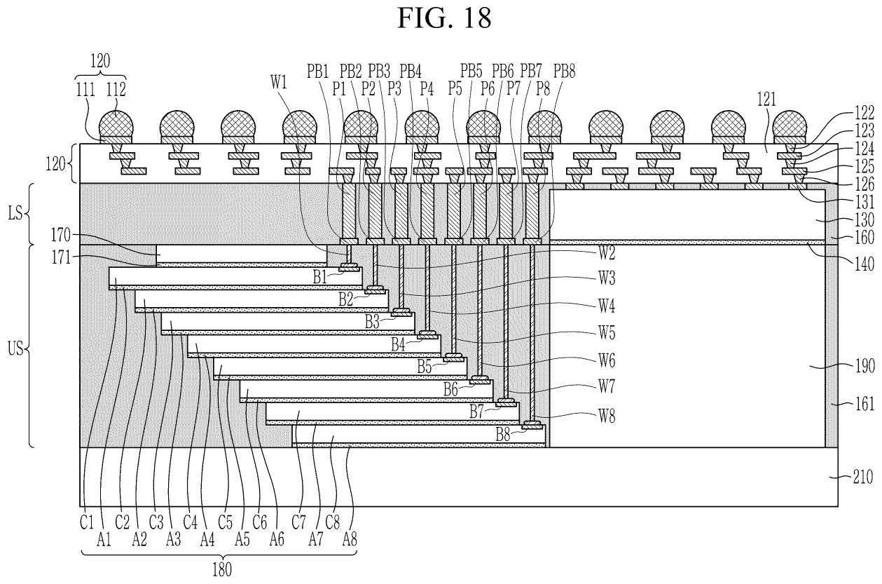

FIG. 18 is a cross-sectional view illustrating a step of forming the external connection structure 110 on the redistribution structure 120.

Referring to FIG. 18, the external access structure 110 may be formed on the redistribution structure 120. The conductive pads 111 may be formed on the first redistribution vias 122 of the redistribution structure 120. In an embodiment, the conductive pad 111 may comprise at least one of copper, nickel, zinc, gold, silver, platinum, palladium, chromium, titanium, and alloys thereof. In an embodiment, the conductive pads 111 may be formed by performing a sputtering process, or by performing an electrolytic plating process after forming a seed metal layer. And then, the external connection member 112 may be formed on each of the conductive pads 111. In an embodiment, the external connection member 112 may comprise at least one of tin, silver, lead, nickel, copper, and an alloy thereof.

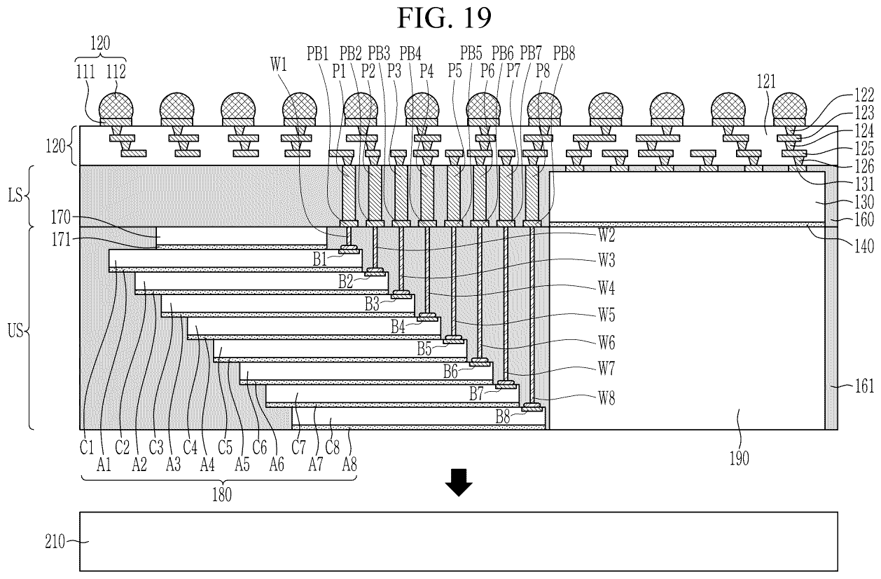

FIG. 19 is a cross-sectional view illustrating a step of removing the carrier 210 from the upper structure US.

Referring to FIG. 19, the carrier 210 may be removed from the upper structure US.

Although preferred embodiments of the present disclosure have been described above, the present disclosure is not limited thereto, various modifications can be implemented within the scope of the patent claims, the detailed description and accompanying drawings, and those obviously fall within the scope of the present disclosure.

What is claimed is:

1. A semiconductor package comprising:
a redistribution structure;
a base die on the redistribution structure;
a plurality of conductive posts on the redistribution structure and beside the base die;
a first molding material covering the base die and the plurality of conductive posts, on the redistribution structure;
a semiconductor stack on the first molding material, wherein the semiconductor stack comprises a plurality of core dies, and the plurality of core dies are sequentially stacked with an offset between adjacent two of the plurality of core dies in a stacking direction of the plurality of core dies;
a plurality of vertical wires, wherein each of the plurality of vertical wires connects a corresponding core die among the plurality of core dies to a corresponding conductive post among the plurality of conductive posts; and
a second molding material covering the semiconductor stack and the plurality of vertical wires, on the first molding material.

2. The semiconductor package of claim 1, wherein:
one of the plurality of conductive posts has a first width in a horizontal direction;
one of the plurality of vertical wires, connected to the one of the plurality of conductive posts, has a second width in the horizontal direction; and
the first width is greater than the second width.

3. The semiconductor package of claim 1, wherein:
the plurality of conductive posts are arranged with a first pitch in a horizontal direction;
the plurality of vertical wires are arranged with a second pitch in the horizontal direction; and
the first pitch is same as the second pitch.

4. The semiconductor package of claim 1, wherein
the base die is configured to control the plurality of core dies.

5. The semiconductor package of claim 1, further comprising
a heat dissipation structure disposed on the base die,
wherein a side surface of the heat dissipation structure is covered by the second molding material.

6. The semiconductor package of claim 1, wherein:
each of the plurality of core dies comprises a plurality of connection pads facing the redistribution structure;
a first end of each of the plurality of vertical wires is connected to the corresponding conductive post among the plurality of conductive posts;
a second end, which is opposite to the first end, of each of the plurality of vertical wires is connected to a corresponding connection pad among the plurality of connection pads.

7. The semiconductor package of claim 6, wherein
each of the plurality of core dies comprises an active surface which is a surface on which the plurality of connection pads thereof is disposed.

8. The semiconductor package of claim 1, wherein
the base die comprises an active surface facing the redistribution structure.

9. The semiconductor package of claim 1, wherein:
the semiconductor stack further comprises a plurality of adhesive members; and
the plurality of core dies alternate with the plurality of adhesive members.

10. A semiconductor package comprising:
a redistribution structure;
a buffer die on the redistribution structure;
a first conductive post array to an Nth conductive post array on the redistribution structure and beside a side surface of the buffer die, wherein N is a natural number greater than or equal to 2 and each of the first conductive post array to the Nth conductive post array is arranged in a row along the side surface of the buffer die;
a first molding material covering the buffer die and the first conductive post array to the N conductive post array, on the redistribution structure;
a spacer structure on the first molding material;
a memory stack on the spacer structure, wherein the memory stack comprises a first memory die to an Nth memory die, and the first memory die to the Nth memory die are sequentially stacked with an offset between adjacent two memory dies in a stacking direction of the first memory die to the Nth memory die;
a first vertical wire array to an Nth vertical wire array, wherein each of the first vertical wire array to the Nth vertical wire array is disposed between a corresponding conductive post array among the first conductive post array to the Nth conductive post array and a corresponding memory die among the first memory die to the Nth memory die, wherein each of the first vertical wire array to the Nth vertical wire array is arranged in a row, on a corresponding conductive post array among the first conductive post array to the Nth conductive post array; and
a second molding material covering the spacer structure, the memory stack, and the first vertical wire array to the Nth vertical wire array, on the first molding material.

11. The semiconductor package of claim 10, wherein
the second molding material does not cover an upper surface of the Nth memory die, and
a bottom surface, opposing the upper surface, of the Nth memory dice faces the redistribution structure.

12. The semiconductor package of claim 10, wherein
each of the first memory die to the Nth memory die is electrically connected to the buffer die through a corresponding vertical wire array among the first vertical wire array to the Nth vertical wire array, a corresponding conductive post array among the first conductive post array to the Nth conductive post array, and the redistribution structure.

13. The semiconductor package of claim 10, wherein
a footprint of the spacer structure is included within a footprint of the first memory die.

14. The semiconductor package of claim 10, wherein:
the first memory die to the Nth memory die are disposed so that the footprint of each of the first memory die to the Nth memory die becomes closer to a footprint of the buffer die in order from the first memory die to the Nth memory die;
the first conductive post array to the conductive post array are disposed so as to become closer to the buffer die in order from the first conductive post array to the Nth conductive post array; and
the first vertical wire array to the Nth vertical wire array are disposed so as to become closer to the buffer die in order from the first vertical wire array to the Nth vertical wire array.

15. A semiconductor package comprising:
a redistribution structure;
a base die on the redistribution structure;
a plurality of conductive posts on the redistribution structure and beside a side surface of the base die;
a first molding material covering the base die and the plurality of conductive posts, on the redistribution structure;
a first dummy structure on the first molding material;
a second dummy structure on the base die;
a memory stack on the first dummy structure, wherein the memory stack comprises a plurality of core dies, wherein the plurality of core dies are sequentially stacked from a bottom with an offset so as to become closer to the side surface of the base die;
a plurality of vertical wires, wherein each of the plurality of vertical wires connects a corresponding core die among the plurality of core dies to a corresponding conductive post among the plurality of conductive posts; and
a second molding material covering the first dummy structure, a side surface of the second dummy structure, the memory stack, and the plurality of vertical wires, on the first molding material.

16. The semiconductor package of claim 15, wherein
an upper surface of the second dummy structure is exposed outside from the second molding material, and
a bottom surface, opposing the upper surface, of the second dummy structure faces the redistribution structure.

17. The semiconductor package of claim 15, wherein
the second dummy structure is thermally connected to the base die.

18. The semiconductor package of claim 15, wherein
the first dummy structure is electrically isolated from the plurality of core dies.

19. The semiconductor package of claim 15, further comprising
a third dummy structure disposed between the redistribution structure and the first dummy structure and having a side surface covered by the first molding material,
wherein another side surface of the third dummy structure is exposed outside from the first molding material.

20. The semiconductor package of claim 19, wherein
the first dummy structure and the third dummy structure are thermally connected to the plurality of core dies.
